(19) United States
(12) Patent Application Publication
(10) Pub. No.: US 2003/0119278 A1
(43) Pub. Date: Jun. 26, 2003

(54) Substrates bonded with oxide affinity agent and bonding method

(76) Inventor: James C. McKinnell, Salem, OR (US)

Correspondence Address: HEWLETT-PACKARD COMPANY, Intellectual Property Administration, P.O. Box 272400, Fort Collins, CO, 80527-2400, US

(21) Appl. No.: 10/029,649

(22) Filed: Dec. 20, 2001

(51) Int. Cl. H01L 21/30

(52) U.S. Cl. 438/455

(57) ABSTRACT

An electrical device has first and second substrates bonded together with a first material. Dispersed within the first material is a reducing agent for the diffusion therein of oxidation of a second material of which at least one of the first and second substrates is composed. The reducing agent has a higher affinity for oxygen than that of the second material.

### FIELD OF THE INVENTION

The present invention relates to bonded substrates, and is more particularly related to bonding substrates with a bonding material that includes an oxide affinity material.

### BACKGROUND OF THE INVENTION

In large scale integration, electrical devices such as complementary metal-oxide semiconductor (CMOS) circuitry are fabricated in large qualities on substrates. These substrates can be bonded together using microfabrication techniques to efficiently manufacture micromachined structures. The term “semiconductor substrate” includes semiconductive material. The term is not limited to bulk semiconductive material, such as a silicon wafer, either alone or in assemblies comprising other materials thereon, and semiconductive material layers, either alone or in assemblies comprising other materials. The term “substrate” refers to any supporting structure including but not limited to the semiconductor substrates described above. A substrate may be made of silicon, glass, gallium arsenide, silicon on sapphire (SOS), epitaxial formations, germanium, germanium silicon, diamond, silicon on insulator (SOI) material, selective implantation of oxygen (SIMOX) substrates, and/or like substrate materials. Preferably, the substrate is made of silicon, which is typically single crystalline.

In some bonding applications, the substrates that are bonded together are semiconductor substrates such as silicon wafers. In wafer bonding, two or more wafers are bonded together each of which can have a plurality of electrical devices formed thereon prior to the wafer bonding process. The bonding process typically forms a controlled environment, such as a hermetic seal, between adjacent wafers. After the wafers are bonded together, they can be are singulated into individual dice, either before or after packaging.

During the fabrication process for each wafer, a native oxide can form on an exposed surface of the wafer. This native oxide can weaken the bond that is formed with another wafer during the bonding process. Native oxide also prevents a uniform bond from forming between adjacent wafers. In order to avoid the native oxide problem, the native oxide is removed using mechanical or ultrasonic scrubbing of the wafer surface. These scrubbing processes are useful only when the bond between surfaces on adjacent wafers do not require precise alignment and are not distributed over an extended area on adjacent wafers. As such, mechanical and ultrasonic scrubbing for native oxide removal is of limited use.

Reverse sputtering can also be used to remove native oxide from substrate surfaces immediately prior to bonding to another substrate. It is desirable to fabricate chips with as few processes and in as short of time in a clean room environment as practical. Short processing time in the clean room environment is desirable because operation and maintenance of the clean room environment for chip fabrication using semiconductor technology processes is time consuming and expensive. Fewer processes in chip fabrication are desirable because each fabrication process is both an expense and an opportunity to reduce yield. Moreover, the extra step of reverse sputtering tends to decrease yield, require additional fabrication tools, and generally adds cost to the wafer bonding process.

Another way to remove native oxide prior to wafer bonding is to etch the native oxide. For example, a silicon surface can be etched to remove its native oxide prior to a noble metal deposition, such as gold, that will be used to form a gold-silicon diffusion bond to another silicon wafer. Variability in the native oxide thickness, which may grow in the time between the etch and a subsequent process step or due to other environmental factors, could increase the variability in the bond between adjacent wafers, thus preventing a uniform bond from forming.

It would be an advance in the art to provide a uniform bond between adjacent substrates by removal of native oxide from the bonding surfaces there between.

### SUMMARY OF THE INVENTION

An electrical device has first and second substrates bonded together with a first material. Dispersed within the first material is a reducing agent for the diffusion therein of oxidation of a second material of which at least one of the first and second substrates is composed. The reducing agent has a higher affinity for oxygen than that of the second material.

These and other features of the present invention will become more fully apparent from the following description and appended claims, or may be learned by the practice of the invention as set forth hereinafter.

### DESCRIPTION OF THE DRAWINGS

To further clarify the above and other advantages and features of the present invention, a more particular description of the invention will be rendered by reference to specific embodiments thereof which are illustrated in the appended drawings. The same numbers are used throughout the drawings to reference like features and components. It is appreciated that these drawings depict only typical embodiments of the invention and are therefore not to be considered limiting of its scope. The invention will be described and explained with additional specificity and detail through the use of the accompanying drawings in which:

FIG. 1 is a cross-sectional view of an embodiment of the invention depicting a cut away section of two wafers to be bonded together by a bonding layer adhered to one of the wafers, where the other wafer has a native oxide thereon;

FIG. 2 is a cross-sectional view of the structure seen in FIG. 1 after further processing, where a wafer bonding process has removed a portion of the native oxide where the wafers are bonded together.

FIG. 3 depicts a flow chart illustrating a bonding process that can be used to fabricate the structures seen in FIGS. 1-2;

FIG. 4 is a cross-sectional view of an embodiment of the invention depicting a cut away section of two wafers to be bonded together by a bonding layer adhered to one of the wafers, where the other wafer has thereon a silicon layer having a native oxide thereon;

FIG. 5 is a cross-sectional view of the structure seen in FIG. 4 after further processing, where a wafer bonding process has removed a portion of the native oxide where the wafers are bonded together.

FIG. 6 depicts a flow chart illustrating a bonding process that can be used to fabricate the structures seen in FIGS. 4-5;

FIG. 7 is a cross-sectional view of another embodiment of the invention depicting a cut away section of two wafers to be bonded together by a triple film stack, where the triple film stack includes an oxide affinity agent layer between two layers of noble metal, where one of the wafers has a native oxide thereon;

FIG. 8 is a cross-sectional view of the structure seen in FIG. 7 after further processing, where a wafer bonding process has removed the native oxide where the wafers are bonded together.

FIG. 9 depicts a flow chart illustrating a bonding process that can be used to fabricate the structures seen in FIGS. 7-8.

FIG. 10 is a cross-sectional view of an embodiment of the invention depicting a cut away section of two wafers to be bonded together by a triple film stack of an oxide affinity agent layer between two layers of noble metal, where one of the wafers has thereon a silicon layer having a native oxide thereon;

FIG. 11 is a cross-sectional view of the structure seen in FIG. 10 after further processing, where a wafer bonding process has removed the native oxide where the wafers are bonded together.

FIG. 12 depicts a flow chart illustrating a bonding process that can be used to fabricate the structures seen in FIGS. 10-11.

FIG. 13 depicts a pair of portions of a respective pair of semiconductor wafers, each having a plurality of electrically insulated integrated circuits fabricated there between, where the portions are bonded together by a bonding structure that forms a closed environment between the portions, and where the portions were formed by scribing and singulating the respective wafers to form individual die for packaging.

### DETAILED DESCRIPTION

The present invention disperses in a bonding material a reducing agent capable of removing oxidation on surfaces to be bonded together such that the oxidation can be removed during the bonding process. When a native oxide is formed upon a surface that is to be joined to another surface, it is desirable to remove the native oxide in order to form a strong and uniform bond to the other surface. By dispersing a reducing agent in a bonding material and then placing the bonding material in contact with the native oxide in a bonding process, the native oxide will be removed. The removal of the native oxide occurs because the agent has a higher affinity for oxygen than the underlying material upon which the native oxide has formed. The agent in the bonding material greatly increases the driving force for the removal of the native oxide, thus enabling a uniform bond between surfaces to be joined together. As the bonding process proceeds at an elevated temperature, the oxygen in the native oxide will diffuse into the bulk of the bonding material. With the agent dispersed in the bonding material, the oxygen will preferentially combine with the agent so as to remove the native oxide at an increased rate.

In silicon wafer bonding, where one silicon wafer is bonded to another silicon wafer, it is desirable to remove native oxide, in any degree of thickness, from both wafer surfaces that are to form an interface there between. One material that can be used to bond the wafers together is gold. It is preferable to co-deposit an agent with the gold so as to remove the native oxide from one or both interface surfaces of the wafers. The free energy of formation of silicon dioxide is recognized as being in a range from about −200 Kcal/mol to about −205 Kcal/mol. As such, the agent in the bonding material should have a higher oxygen affinity than silicon, meaning that the free energy of formation must be more negative than either gold or silicon dioxide, or less than a range from about −200 Kcal/mol to about −205 Kcal/mol. The oxide of the agent is therefore more stable than silicon dioxide.

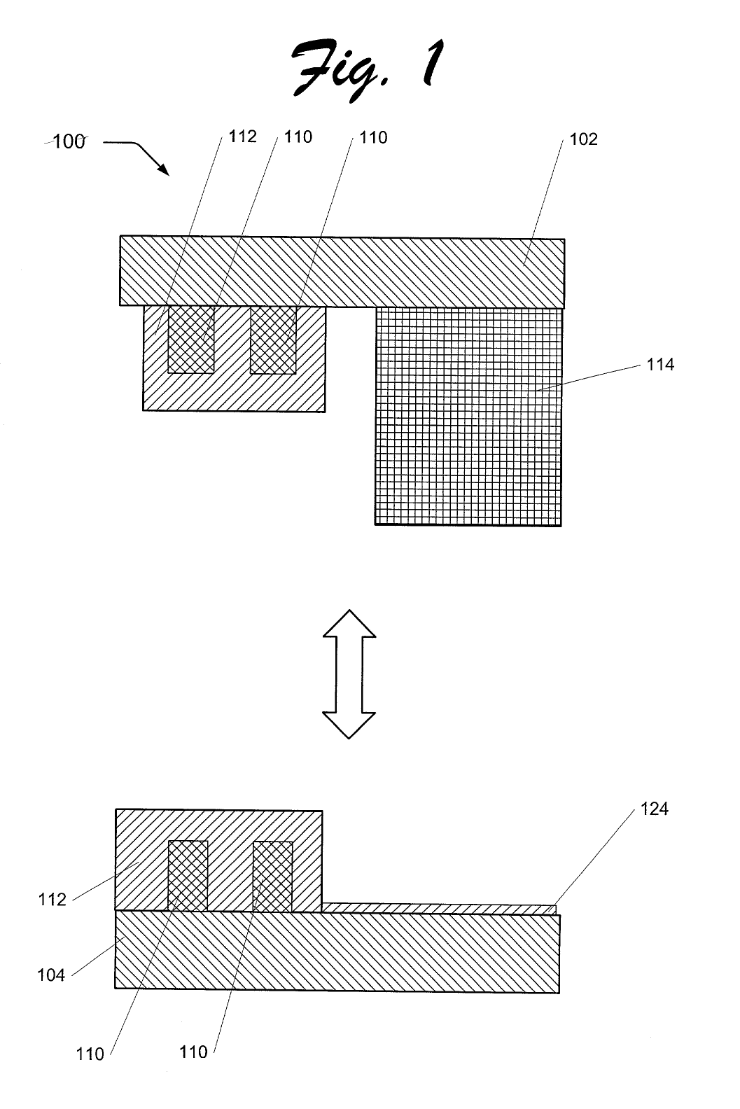

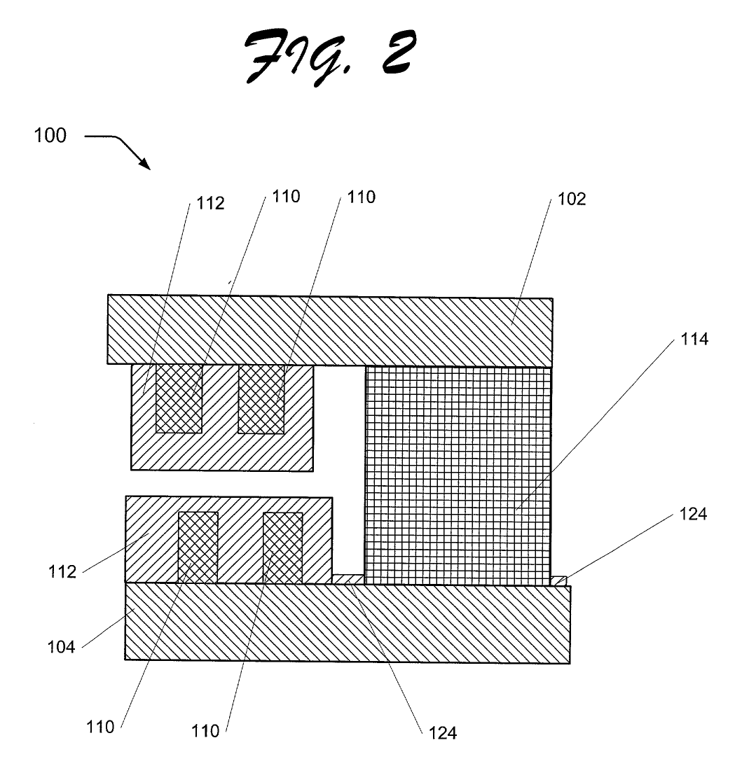

FIGS. 1-2 show views of a structure 100 in electrical devices that can be formed using microfabrication techniques. Two (2) substrates are seen in structure 100. By way of example, each substrate can be a wafer composed of a semiconductor material such as silicon. FIG. 1 shows a wafer 102 to be bonded to a wafer 104. Each wafer 102, 104 may include other layers and/or circuitry not shown for simplicity in order to implement other various functionalities. As seen in FIG. 1, circuitry 110 is fabricated on each wafer 102, 104. Circuitry 110 can include microcircuitry such as CMOS components.

In a preferred embodiment of the invention, wafers 102, 104 have an insulator 112 deposited and patterned over circuitry 110 on each wafer 102, 104. Insulator 112 may be comprised of any suitable insulating material known in the art, including but not limited to a wet or dry silicon dioxide (SiO₂), a nitride material including silicon nitride, tetraethylorthosilicate (S₁-OC₂H₅)₄) (TEOS) based oxides, borophosphosilicate glass (BPSG), phosphosilicate glass (PSG), borosilicate glass (BSG), oxide-nitride-oxide (ONO), polyamide film, tantalum pentoxide (Ta₂O₅), plasma enhanced silicon nitride (P—SiNₓ), titanium oxide, oxynitride, germanium oxide, a spin on glass (SOG), any chemical vapor deposited (CVD) dielectric including a deposited oxide, a grown oxide, and/or like dielectric materials.

A native oxide 124 forms upon wafer 104 due to environmental conditions. A bonding layer 114 is formed on wafer 102 and is preferably composed of an alloy that is formed by a physical vapor deposition process (PVD) using a powdered target or a target composed of an alloy. Bonding layer 114 can be formed so as to be patterned, such as by use of an etch process in combination with directional sputtering, a deposition mask, a collimator, or combinations thereof. The thickness of bonding layer 114 is preferably in a range from about 50 Angstroms to about 20,000 Angstroms. Since the material of which bonding layer 114 is composed is capable of conducting current, bonding layer 114 can be used as an electrical connection between circuitry 110 included within wafers 102, 104. The PVD process preferably co-sputters a noble metal, such as gold or a gold alloy, with a reducing agent that has a higher affinity for oxygen than does the material of which wafer 104 is composed. As used herein, a noble metal is intended to mean any of several metallic chemical elements that have outstanding resistance to oxidation, even at high temperatures. These metallic chemical elements include rhenium, ruthenium, rhodium, palladium, silver, osmium, iridium, platinum, and gold, and are more particularly characterized as the metals of groups VIIb, VIII, and Ib of the second and third transition series of the periodic table.

The result of the co-sputtering process is the formation of an alloy of which bonding layer 114 is composed. By way of example, when wafer 104 is composed of silicon, and the noble metal is gold or a gold alloy, the agent that is co-sputtered and thereby alloyed with the gold or gold alloy can be Al, As, B, Ca, Ce, Co, Cr, Fe, Ga, Hf, In, La, Li, Mg, Mn, Nb, Nd, Ge, Pr, Sb, Si, Ta, Th, Ti, V, W, Zr, or alloy thereof, with the PVD process being conducted in a temperature range from about 100 degrees Centigrade to about 1000 degrees Centigrade. More preferably, the noble metal will be gold and the co-sputtered material will be Ti Al, Li, Mg, Ca, or an alloy thereof, with the PVD process being conducted in a temperature range from about 100 degrees Centigrade to about 1000 degrees Centigrade. Preferably, the material that is co-sputtered with the noble metal will be less than about half of the weight of bonding layer 114 and will have a free energy that is lower than that of silicon dioxide or lower than a range that is from about −200 Kcal/mol to about −205 Kcal/mol.

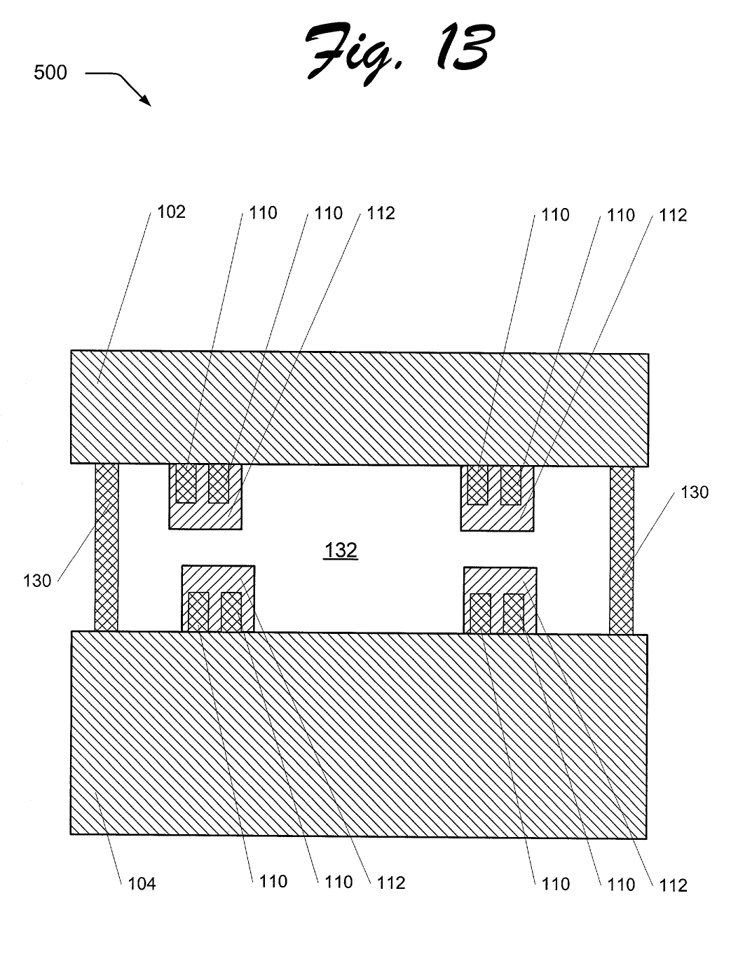

Following the PVD process, bonding layer 114 is patterned as seen in FIG. 1. Wafers 102, 104 are pressed together with bonding layer 114 there between. The bonding together of wafers 102, 104 may be of any suitable configuration as long as the bonding materials can be bonded at compatible temperatures for microcircuitry fabrication applications. The bonding process, which can be an annealing process, causes bonding layer 114 to form a bond between wafers 102, 104 to create the single structure 100 seen in FIG. 2. When wafers 102, 104 are bonded together by bonding layer 114 as seen in FIG. 2, a region having a closed environment and/or a hermetic sealed region can thereby be formed between wafers 102, 104. An example of the formation of a closed environment is seen in FIG. 13 where a structure 500 has a bonding structure 130 that bonds wafers 102, 104 together to form a closed environment 132 there between. Bonding structure 130 forms a seal between wafers 102, 104. As such, circuits 110, which are electrically insolated within insulator 112 on both of wafers 102, 104, are within closed environment 132.

A bond is “sufficient” for the purposes of the present invention when it is capable of maintaining an alignment of wafer 102 with respect to wafer 104 during normal operation of the structure 100. As such, after the bonding process, the bond should be sufficient to keep wafer 102 attached and aligned to wafer 104 as well being configured to form an electrical connection between the integrated circuits 110 in wafer 102 and the integrated circuits 110 in wafer 104.

In the bonding process, wafers 102, 104 are preferably pressed together at a pressure of about 10 KPa to about 300 MPa to form a bond between wafer 104 and bonding layer 114 of wafer 102. An annealing chamber can be used to accomplish the bonding process. Although not necessary for implementing the invention, it may be preferable to change or “ramp” the temperature. Preferably, the bonding or annealing temperature of the bonding process will be at or below approximately 450 degrees Celsius. By keeping temperatures of the bonding or annealing process below approximately 450 degrees Celsius, any CMOS circuitry included in either of the wafers 102, 104 should not be damaged. FIG. 2 reflects the absence of native oxide 124 where bonding layer 114 has made contact therewith. Native oxide 124 is removed by diffusion into bonding layer 114. Included in bonding layer 114 is noble metal and an oxide affinity material that is dispersed within the noble metal of bonding layer 114. The oxide affinity material reacts with the native oxide.

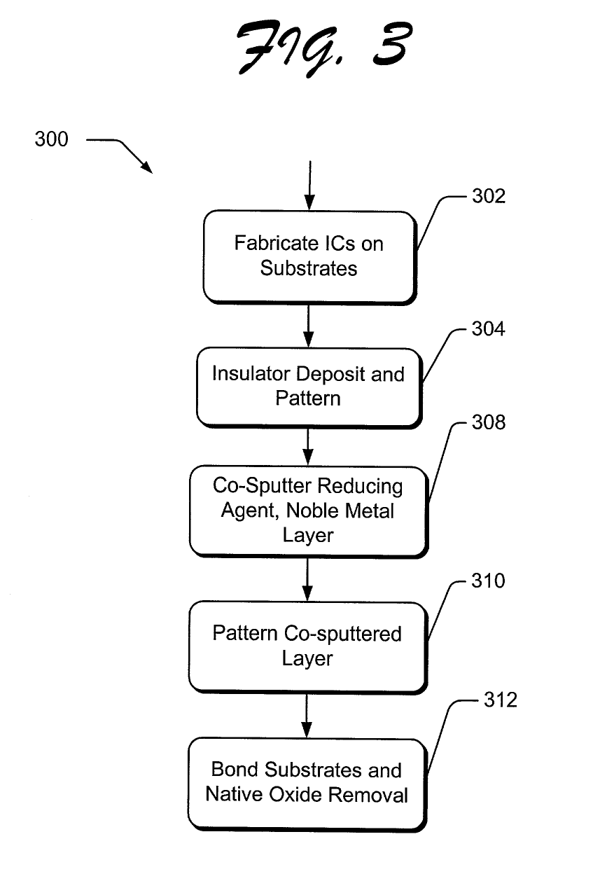

FIG. 3 is a flow chart showing a process 300 for fabricating structure 100 seen in FIGS. 1-2. Structure 100 is an electrical device made by bonding surfaces together with a material having dispersed therein a reducing agent into which oxidation on the surfaces is diffused to remove the oxidation while bonding. In accordance with the flow chart seen in FIG. 3, at step 302 integrated circuits (ICs) are fabricated on a plurality of substrates, each of which may be wafers 102, 104. At step 304 an insulator is deposited and patterned over the ICs, such as is seen in FIG. 1 at reference numeral 112 on each of wafers 102, 104. At step 308 a reducing agent is co-sputtered with a noble metal upon one of the wafers. At step 310, the co-sputtered layer is patterned to form a bonding layer 114 seen in FIG. 1. The wafers are bonded at step 312 in a bonding process that removes a portion of a native oxide where the patterned co-sputtered layer contacts the other wafer, as seen in structure 100 seen in FIG. 2. One skilled in the art should realize that a variety of temperatures, times, and pressures are possible for the bonding process depicted by FIG. 3.

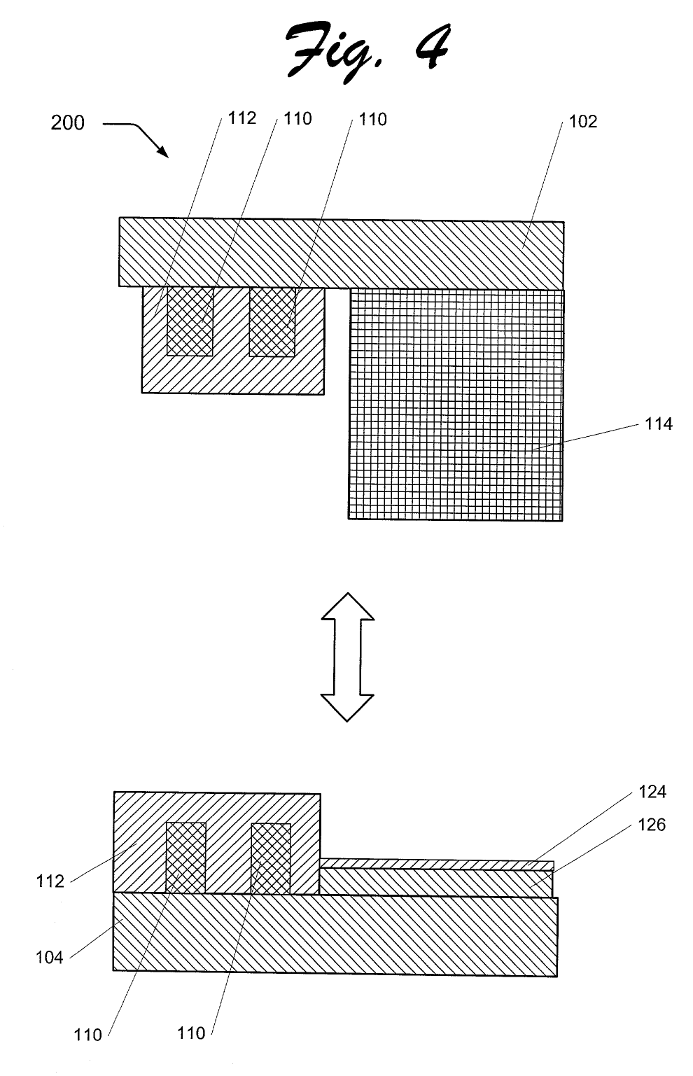

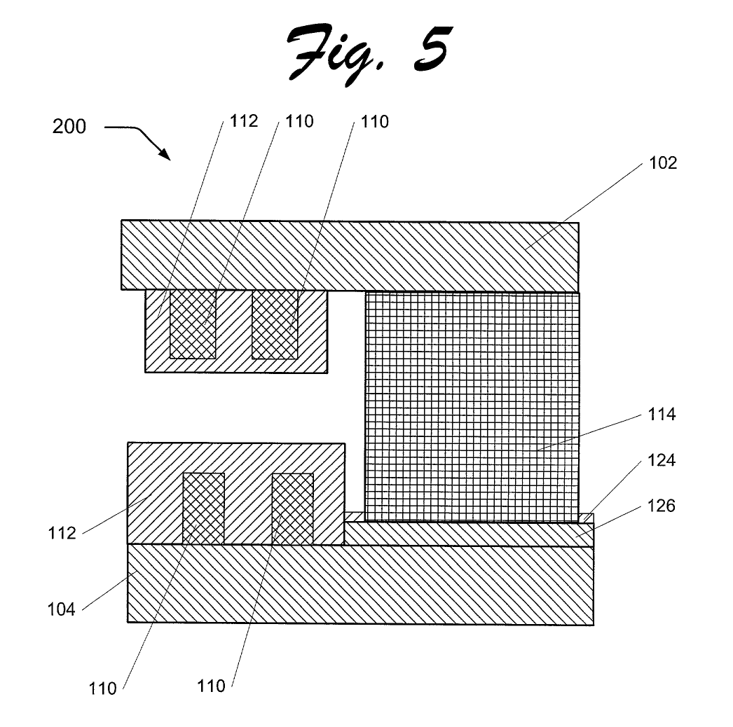

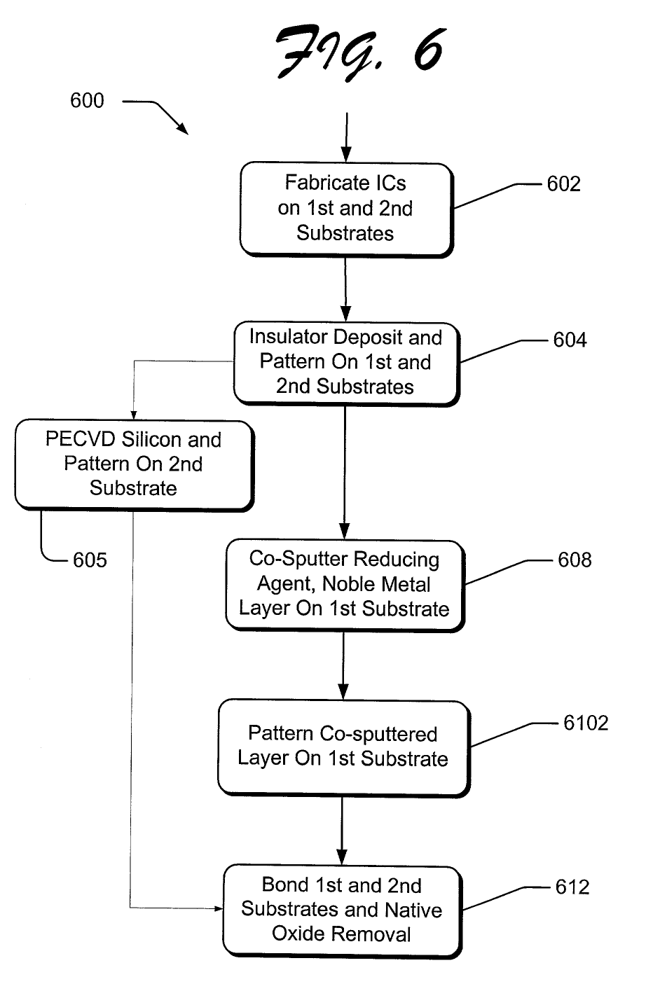

Another embodiment of the invention is depicted in FIGS. 4-5 where a structure 200 is fabricated using a process 600 of FIG. 6. FIGS. 4-5 differ from FIGS. 1-2 in that native oxide region 124 is upon silicon layer 126 on wafer 104. Silicon layer 126 is preferably formed by plasma enhanced chemical vapor deposition (PECVD) and is subsequently patterned as seen in structure 200 of FIG. 4. As seen in FIG. 5, bonding layer 114 on wafer 102 is bonded to PECVD silicon layer 126 on wafer 104. During the bonding of wafers 102, 104, there is a removal of a portion of native oxide layer 124 on silicon layer 126 as seen in FIG. 5. As such, the removed portion of native oxide layer 124 diffuses into bonding layer 114, and bonding layer 114 bonds to PECVD silicon layer 126 so as to form structure 200 as seen in corresponding FIG. 5. Process 600 in FIG. 6 is similar to process 300 in FIG. 3 with the addition of step 605 that deposits and patterns the PECVD silicon layer 126. Structure 200 of FIGS. 4-5 thereby can be used to form closed environment 132 as seen in FIG. 13.

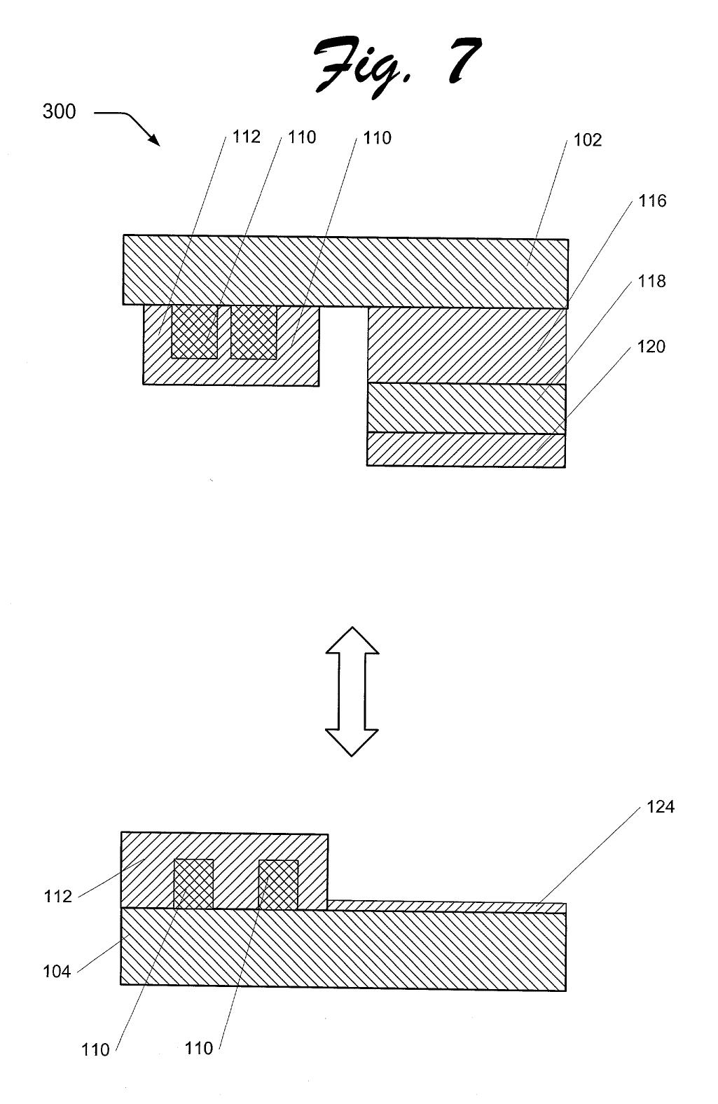

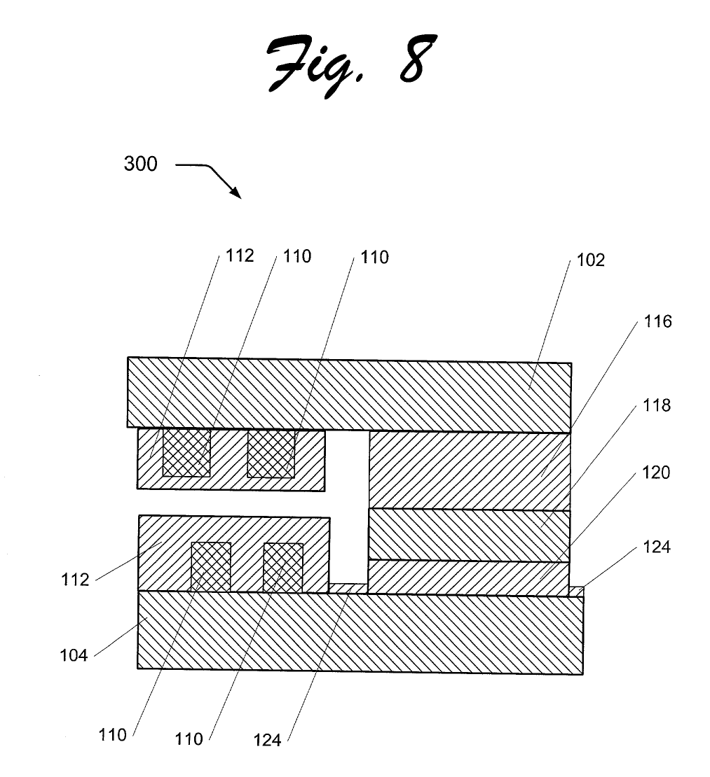

Another embodiment of the invention is depicted in FIGS. 7-8 which differ from FIGS. 1-2 in that bonding layer 114 of structure 100 is replaced with a triple film stack in structure 300. Like bonding layer 114 of structure 100, the triple film stack of structure 100 is adhered to wafer 102. The triple film stack is used to bond surfaces together and has a reducing agent into which oxidation is diffused to remove the oxidation while bonding. In FIG. 7, the triple film stack includes a noble metal trace 116. Noble metal trace 116 is preferably composed of gold or an alloy thereof, and can be formed by conventional deposition techniques which will preferably be a PVD process. An agent layer 118 is formed upon noble metal trace 116 and will preferably having a thickness in a range from about 0.1 microns to not more than about 2 microns. Agent layer 118 will preferably be formed by sputtering a target composed of Al, As, B, Ca, Ce, Co, Cr, Fe, Ga, Hf, In, La, Li, Mg, Mn, Nb, Nd, Ge, Pr, Sb, Si, Ta, Th, Ti, V, W, Zr, or an alloy thereof, with the PVD process being conducted in a temperature range from about 100 degrees Centigrade to about 1000 degrees Centigrade. More preferably, when noble metal trace 116 is composed of gold, then the agent layer 118 will be composed of Ti Al, Li, Mg, Ca, or an alloy thereof.

A noble metal cap 120, preferably composed of gold or an alloy thereof, is seen in FIGS. 7-8 as being formed upon agent layer 118. Noble metal cap 120 will preferably have a thickness of less than about 2 microns and most preferably in a range from about 50 Angstroms to about 100 Angstroms. Noble metal cap 120 will preferably be continuous upon agent layer 118 and will be formed using conventional deposition equipment. Noble metal cap 120 prevents agent layer 118 from reacting with gases in the ambient. Preferably, agent layer 118 will form a composite structure with both noble metal trace 116 and noble metal cap 120 prior to or during a process that bonds wafers 102, 104 together.

After noble metal cap 120 is formed, a patterning of noble metal trace 116, agent layer 118, and noble metal cap 120 takes place to form the representation thereof seen in FIGS. 7-8.

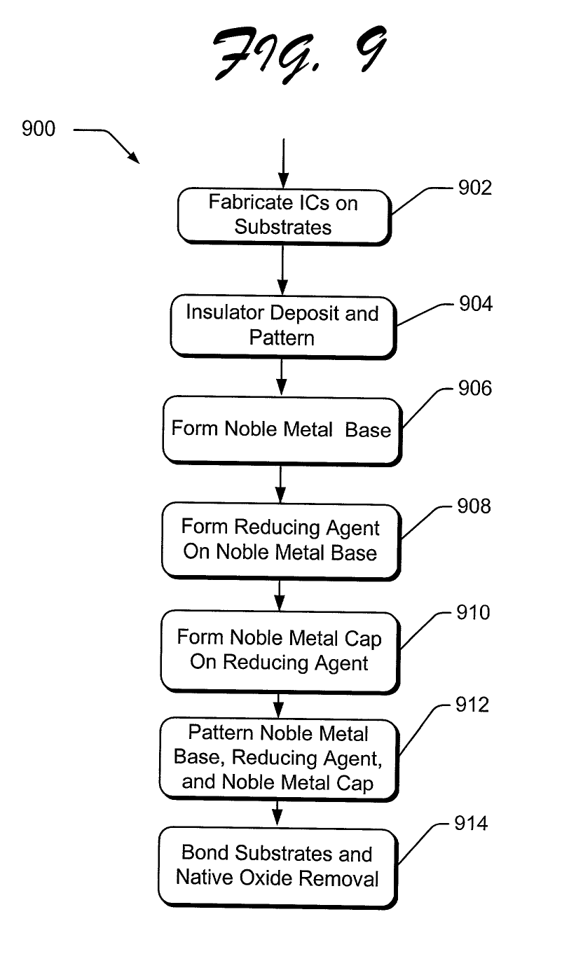

FIG. 8 shows wafers 102, 104 being pressed together with the patterned noble metal trace 116, agent layer 118, noble metal cap 120 there between. Wafer 102 is bonded to wafer 104 similar to the bonding process described above with respect to FIGS. 1-3, and during which a top of native oxide 124 is removed from an exposed surface of wafer 104. Particularly, noble metal cap 120 is brought into contact with native oxide 124 on wafer 104 under pressure and elevated temperature in the bonding process, as particularly depicted in the process steps seen in FIG. 9 which are discussed below.

Substrate bonding process 900 is illustrated in a flow chart seen in FIG. 9, where the bonding process 900 corresponds to the structure 300 depicted in FIGS. 7-8. In accordance with the flow chart seen in FIG. 9, at step 902 integrated circuits (ICs) are fabricated on a plurality of substrates, each of which may be silicon wafer. At step 904 an insulator is deposited and patterned over the ICs, such as is seen in FIGS. 7-8 at reference numeral 112. At step 906, a noble metal base is formed. At step 908, a reducing agent is formed upon the noble metal base. At step 910, a noble cap is formed on the reducing agent. The noble metal base, the reducing agent, and the noble metal cap are all patterned at step 912. The substrates are bonded together at step 914 as seen in FIG. 8 so as to form a closed environment and/or a hermetic seal between wafers 102, 104, similar to that seen in FIG. 13. As seen in structure 300 in FIG. 8, a portion of native oxide 124 is removed from wafer 104 where patterned metal cap 120 contacts wafer 104 during the wafer bonding process.

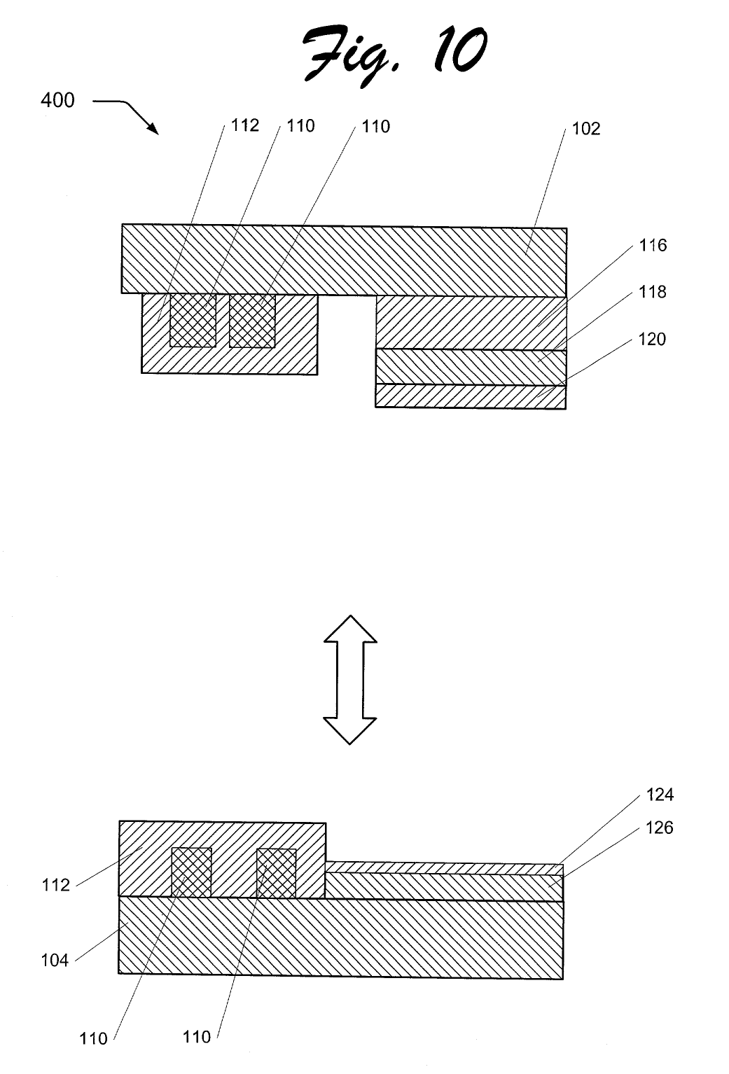

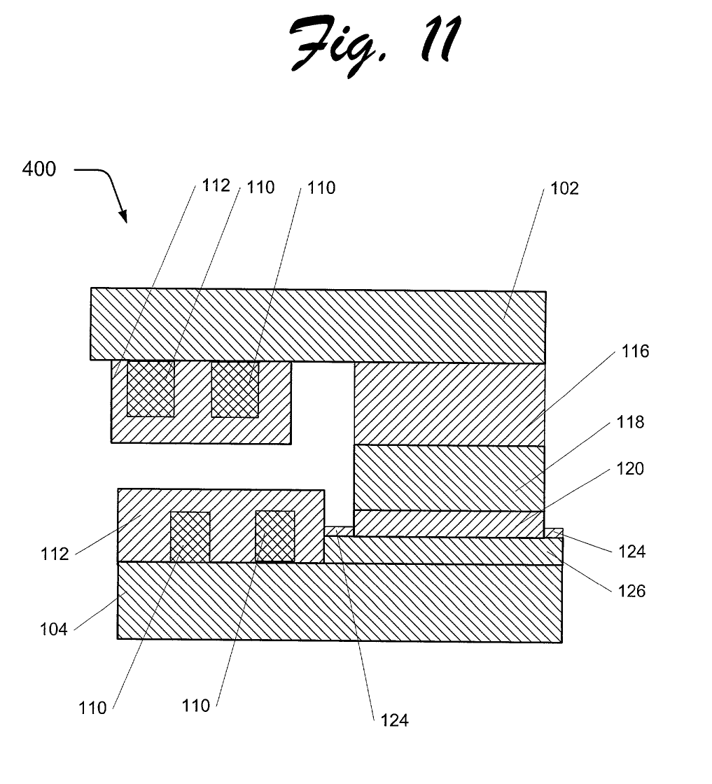

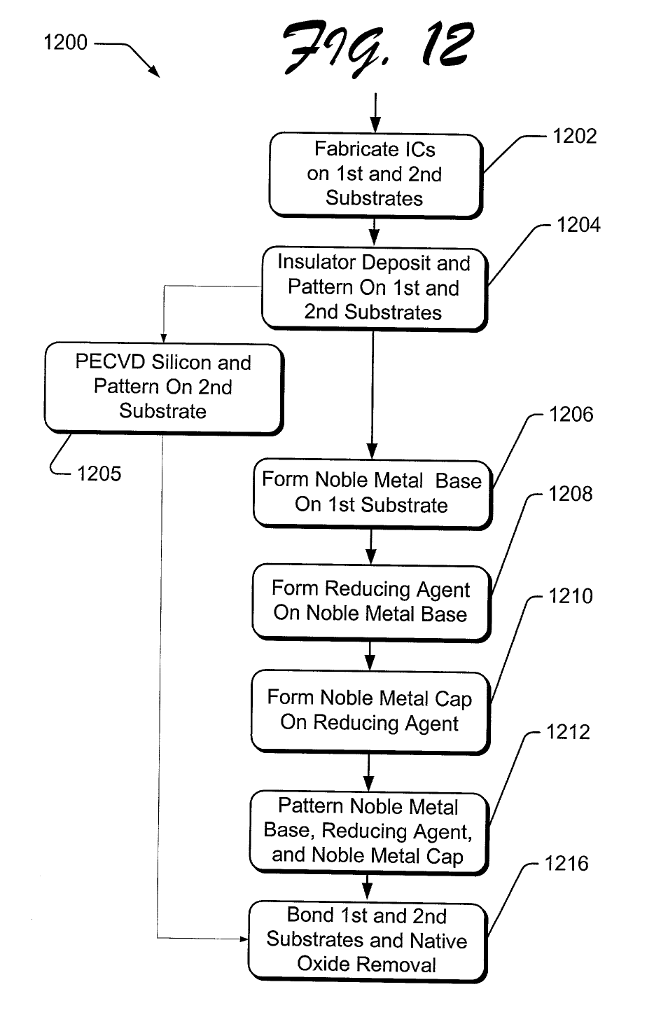

Another embodiment of the invention is depicted in FIGS. 10-11 where a structure 400 is fabricated using a process 1200 of FIG. 12. FIGS. 10-11 differ from FIGS. 7-8 in that native oxide region 124 is upon silicon layer 126 on wafer 104. Silicon layer 126 is formed by plasma enhanced chemical vapor deposition (PECVD) and is subsequently patterned as seen in structure 400 of FIGS. 10-11. As seen in FIG. 11, noble metal cap 120 on wafer 102 is bonded to silicon layer 126 on wafer 104 during which there is a removal of a portion of the top native oxide layer 124. As such, the removed portion of the top native oxide layer 124 diffuses into noble metal cap 120 and noble metal cap 120 bonds to silicon layer 126 to form structure 400 as seen in corresponding FIG. 11. Process 1200 in FIG. 12 is similar to process 900 in FIG. 9 which the addition of step 1205 that deposits and patterns the PECVD silicon layer 126. Structure 400 of FIGS. 10-11 thereby can be used to form closed environment 132 as seen in FIG. 13.

Following each bonding process 300, 600, 900, and 1200 in FIGS. 3, 6, 9, and 12, respectively, the bonded substrates can be scribed and singulated to form individual die. Each die can be packaged before or after the singulation process so as to contain there within a closed environment and/or a hermetic seal.

The embodiments of the invention disclosed herein for forming bonded wafer structures, and packaged die therefrom, can be fabricated using known process equipment in a semiconductor fabrication operation and can allow for a broad range of materials and dimensions for said structures. It should be recognized that, in addition to the bonded substrate embodiments of the invention that are described above, this invention is also applicable to alternative bonded structure technologies in electrical devices, such as a die that encapsulates a closed environment or hermetically sealed atmosphere, MicroElectroMechanical Systems (MEMS), air bags applications, field emitter display devices, accelerometers, bolometers, mirror arrays, optical switches, pressure gauges, turbine chambers, combustion chambers, and multiple wafers memory devices such as are used for Atomic Resolution Storage (ARS) and the like.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An electrical device comprising:
first and second substrates, at least one having a semiconductor layer thereon; and
a bond structure bonding the first substrate to the second substrate, the bond structure including an alloy bonded to the semiconductor layer and composed of noble metal alloyed with an oxide affinity material having an affinity for oxygen higher than that of the material of which the semiconductor layer is composed.

2. The electrical device as defined in claim 1, wherein the oxide affinity material is not more than about half the weight of the alloy interfacing the semiconductor layer.

3. The electrical device as defined in claim 1, further comprising electrical insulation, situated between the first and second substrates, for electrically isolating a plurality integrated circuits.

4. The electrical device as defined in claim 1, further comprising a region having a closed environment between the first and second substrates, wherein the region is defined at least in part by the bond structure.

5. The electrical device as defined in claim 1, further comprising a hermetically sealed region between the first and second substrates, wherein the hermetically sealed region is defined at least in part by the bond structure.

6. The electrical device as defined in claim 1, wherein the alloy bonded to the semiconductor layer is sufficient to maintain an alignment of said first substrate with respect to the second substrate.

7. The electrical device as defined in claim 1, wherein the alloy bonded to the semiconductor layer is composed of noble metal alloyed with an oxide affinity material having a free energy that is lower than that of silicon dioxide.

8. The electrical device as defined in claim 1, wherein the alloy bonded to the semiconductor layer is composed of noble metal alloyed with a material having a free energy less than a range from about −200 Kcal/mol to about −205 Kcal/mol.

9. The electrical device as defined in claim 1, wherein the alloy bonded to the semiconductor layer is composed of noble metal alloyed with a material selected from the group consisting of Al, As, B, Ca, Ce, Co, Cr, Fe, Ga, Hf, In, La, Li, Mg, Mn, Nb, Nd, Ge, Pr, Sb, Si, Ta, Th, Ti, V, W, and Zr.

10. An electrical device comprising first and second semiconductor wafers each including a plurality of integrated circuits, wherein:
the first semiconductor wafer has a silicon layer thereon;
the silicon layer on the first semiconductor wafer is bonded to the second semiconductor wafer by gold alloyed with an oxide affinity material having an oxygen affinity higher than that of silicon.

11. The electrical device as defined in claim 10, wherein the oxide affinity material makes up not more than about half the weight of the gold.

12. The electrical device as defined in claim 10, wherein the silicon layer on the first semiconductor wafer has a native oxide layer thereon.

13. The electrical device as defined in claim 10, further comprising a closed environment between the first and second semiconductor wafers that is defined in part by:
the silicon layer on the first semiconductor wafer; and
the gold alloyed with the oxide affinity material.

14. The electrical device as defined in claim 10, further comprising a hermetically sealed region between the first and second semiconductor wafers that is defined in part by:
the silicon layer on the first semiconductor wafer; and the gold alloyed with the oxide affinity material.

15. An electrical device comprising:
first and second semiconductor wafers each including a plurality of integrated circuits;
silicon on the first semiconductor wafer; and
a bonding structure including gold alloyed with a material having a free energy lower than that of silicon dioxide, wherein the first semiconductor wafer is bonded to the second semiconductor wafer by the gold alloy that is bonded to the silicon on the first semiconductor wafer.

16. The electrical device as defined in claim 15, wherein the free energy of the material is less than a range from about −200 Kcal/mol to about 205 Kcal/mol.

17. The electrical device as defined in claim 15, wherein the material selected from the group consisting of Ti Al, Li, Mg, and Ca.

18. An electrical device comprising:
first and second substrates each including a plurality of integrated circuits and the first substrate having a semiconductor layer thereon;
a bonding structure having opposing ends respectively upon the semiconductor layer of the first substrate and the second substrate, the bonding structure including:
a noble metal base layer upon the second substrate;
an oxide affinity material in contact with the noble metal base layer and having an affinity for oxygen higher than that of the material of which the semiconductor layer is composed; and
a noble metal interface between the oxide affinity material and the semiconductor layer, wherein the first substrate is bonded to the second substrate by the bonding structure.

19. The electrical device as defined in claim 18, wherein:
the oxide affinity material has a thickness in a range from about 0.1 microns to not more than about 2 microns; and
the noble metal interface has a thickness not more than about two microns.

20. The electrical device as defined in claim 18, wherein the oxide affinity material in contact with the noble metal base layer is selected from the group consisting of A1, As, B, Ca, Ce, Co, Cr, Fe, Ga, Hf, In, La, Li, Mg, Mn, Nb, Nd, Ge, Pr, Sb, Si, Ta, Th, Ti, V, W, and Zr.

21. The electrical device as defined in claim 18, further comprising a region having a closed environment between the first and second substrates and defined in part by the bonding structure, wherein the plurality of integrated circuits are within the closed environment.

22. The electrical device as defined in claim 21, wherein the closed environment is a hermetically sealed region.

23. The electrical device as defined in claim 18, wherein the oxide affinity material in contact with the noble metal base layer has a free energy that is lower than that of silicon dioxide.

24. The electrical device as defined in claim 18, wherein the oxide affinity material in contact with the noble metal base layer has a free energy less than a range from about −200 Kcal/mol to about −205 Kcal/mol.

25. An electrical device comprising:
first and second semiconductor wafers each including a plurality of integrated circuits and the first semiconductor wafer have a silicon layer thereon;
a bonding structure having opposing ends respectively on the silicon layer and the second semiconductor wafer, the bonding structure including:
a gold base layer upon the first semiconductor wafer;
an oxide affinity material in contact with the gold metal base layer and having an affinity for oxygen higher than that of silicon; and
a gold interface between the oxide affinity material and with the silicon layer, wherein the first semiconductor wafer is bonded to the second semiconductor wafer by the bonding structure.

26. The electrical device as defined in claim 25, wherein the oxide affinity material has a thickness in a range from about 0.1 microns to not more than about 2 microns.

27. The electrical device as defined in claim 25, wherein the silicon layer has a native oxide thereon.

28. The electrical device as defined in claim 25, further comprising a region having a closed environment between the first and second semiconductor wafers and defined in part by the bonding structure, wherein the plurality of integrated circuits are within the closed environment.

29. The electrical device as defined in claim 28, wherein the closed environment is a hermetically sealed region.

30. An electrical device comprising first and second semiconductor wafers each including a plurality of integrated circuits enclosed within a sealed region that is defined in part by a bonding structure bonding the first semiconductor wafer to the second semiconductor wafer and including:
a silicon material;
a gold base layer upon the silicon material;
an oxide affinity material in contact with the gold metal base layer and having a free energy lower than that of silicon dioxide; and
a noble metal interface on the oxide affinity material.

31. The electrical device as defined in claim 30, wherein the oxide affinity material has a free energy less than a range from about −200 Kcal/mol to about −205 Kcal/mol.

32. The electrical device as defined in claim 30, wherein the oxide affinity material is selected from the group consisting of Ti Al, Li, Mg, and Ca.

33. An electrical device comprising first and second substrates bonded together with a first material having dispersed therein a reducing agent for the diffusion therein of oxidation of a second material of which at least one of the first and second substrates is composed, wherein the reducing agent has a higher affinity for oxygen than that of the second material

34. The electrical device as defined in claim 33, wherein:
the first material comprises gold; and
the second material comprises silicon.

35. A substrate bonding method comprising bonding together a semiconductor layer on a first substrate to an alloy interface on a second substrate that is composed of noble metal alloyed with an oxide affinity material having an affinity for oxygen higher than that of the material of which the semiconductor layer is composed.

36. The method as defined in claim 35, wherein the bonding together comprises the steps of:
co-sputtering the oxide affinity material with the noble metal upon native oxide on the second substrate; and
pressing the co-sputtered oxide affinity material and noble metal against a native oxide that is on the semiconductor layer on the first substrate, wherein during said pressing:
the native oxide that is on the semiconductor layer on the first substrate is diffused into the noble metal that contains the oxide affinity material and reacts with the dispersion of the oxide affinity material within the noble metal; and
the noble metal is alloyed with the oxide affinity material.

37. A substrate bonding method comprising bonding together a silicon layer on a first substrate with an alloy interface on a second substrate, the alloy interface being composed of noble metal alloyed with an oxide affinity material having a free energy that is lower than that of silicon dioxide.

38. The method as defined in claim 37, wherein the bonding together comprises the steps of:
co-sputtering the oxide affinity material with the noble metal upon the second substrate; and
pressing the co-sputtered oxide affinity material and noble metal against a native oxide that is on the silicon layer on the first substrate, wherein during said pressing:
the native oxide on the silicon layer is removed by diffusing into the noble metal upon the second substrate and reacting with the oxide affinity material;
the noble metal is alloyed with the oxide affinity material; and
the first substrate is bonded to the second substrate.

39. The method as defined in claim 38, wherein the pressing further comprises the step of forming the alloy interface so as to be sufficient to maintain an alignment of said first substrate with respect to the second substrate.

40. The method as defined in claim 37, wherein the oxide affinity material is not more than about half the weight of the alloy interface.

41. The method as defined in claim 37, further comprising, prior to the step of bonding together a silicon layer on a first substrate with an alloy interface on a second substrate, the step of forming a plurality of integrated circuits in at least one of the first and second substrates.

42. The method as defined in claim 41, wherein:
the step of bonding together a silicon layer on a first substrate with an alloy interface on a second substrate forms a region having a closed environment between the first and second substrates; and
the plurality of integrated circuits in at least one of the first and second substrates are within the region having the closed environment

43. The method as defined in claim 42, wherein the region having the closed environment is a hermetically sealed region.

44. The method as defined in claim 37, wherein:
the noble metal comprises gold or a gold alloy; and
the oxide affinity material is selected from the group consisting of Al, As, B, Ca, Ce, Co, Cr, Fe, Ga, Hf, In, La, Li, Mg, Mn, Nb, Nd, Ge, Pr, Sb, Si, Ta, Th, Ti, V, W, and Zr.

45. The method as defined in claim 44, wherein the oxide affinity material is selected from the group consisting of Ti Al, Li, Mg, and Ca.

46. The method as defined in claim 37, wherein, prior to the bonding together a silicon layer on a first substrate with an alloy interface on a second substrate, the silicon layer on the first substrate has a native oxide thereon.

47. A substrate bonding method comprising the steps of:
forming a plurality of integrated circuits in at least one of first and second substrates;
forming a semiconductor layer on the first substrate;
forming a noble metal base layer upon the second substrate;
forming an oxide affinity material in contact with the noble metal base layer, the oxide affinity material having an affinity for oxygen higher than that of the material of which the semiconductor layer is composed;
forming a noble metal interface upon the oxide affinity material; and
pressing the semiconductor layer on the first substrate against the noble metal interface in order to:
remove a native oxide on the semiconductor layer by diffusion into the noble metal interface and reaction with the oxide affinity material; and
form a bond between the first and second substrates.

48. The method as defined in claim 47, wherein the pressing further comprises forming the bond of the first substrate to the second substrates so as to be sufficient to maintain an alignment of said first substrate with respect to the second substrate.

49. The method as defined in claim 47, wherein:
the oxide affinity material has a thickness in a range from about 0.1 microns to not more than about 2 microns; and
the noble metal interface has a thickness of not more than about two microns.

50. The method as defined in claim 47, wherein, prior to the pressing, the semiconductor layer on the first substrate has a native oxide thereon.

51. The method as defined in claim 47, wherein the pressing forms a region between the first and second substrates having a closed environment in which are situated the plurality of integrated circuits in at least one of first and second substrates.

52. The method as defined in claim 47, wherein:
the material of which the semiconductor layer is composed comprises silicon;
the noble metal comprises gold or a gold alloy; and
the oxide affinity material is selected from the group consisting of Al, As, B, Ca, Ce, Co, Cr, Fe, Ga, Hf, In, La, Li, Mg, Mn, Nb, Nd, Ge, Pr, Sb, Si, Ta, Th, Ti, V, W, and Zr.

53. The method as defined in claim 47, wherein the pressing forms a composite of:
the semiconductor layer;
the noble metal interface;
the oxide affinity material; and
the noble metal base layer.

54. The method as defined in claim 53, wherein the composite further comprises the first substrate.

55. A surface bonding method comprising bonding surfaces together with a material having dispersed therein a reducing agent into which oxidation on at least one of the surfaces is diffused to remove the oxidation from the at least one of the surfaces during the bonding.

56. The method as defined in claim 55, wherein the reducing agent is not more than about half the weight of the material that bonds the surfaces together.

57. The method as defined in claim 55, further comprising, prior to the step of bonding, the step of forming a plurality of integrated circuits on at least one of the surfaces, wherein the bonding surfaces together forms a closed environment between the surfaces in which are situated the plurality of integrated circuits on at least one of the surfaces.

58. The method as defined in claim 55, wherein:
the surface on which the oxidation is situated is composed of silicon;
the material that bonds the surfaces together comprises gold or a gold alloy; and
the reducing agent is selected from the group consisting of Al, As, B, Ca, Ce, Co, Cr, Fe, Ga, Hf, In, La, Li, Mg, Mn, Nb, Nd, Ge, Pr, Sb, Si, Ta, Th, Ti, V, W, and Zr.

59. The method as defined in claim 58, wherein, prior to the bonding, the silicon surface has a native oxide thereon.
